(19) United States
(12) Patent Application Publication
(10) Pub. No.: US 2025/0192082 A1
(43) Pub. Date: Jun. 12, 2025

(54) SEMICONDUCTOR PACKAGE INCLUDING STACKED CHIPS

(71) Applicant: SAMSUNG ELECTRONICS CO., LTD., SUWON-SI (KR)

(72) Inventors: Sangmin LEE, Suwon-si (KR); Keumhee MA, Suwon-si (KR); Jongpa HONG, Suwon-si (KR)

(21) Appl. No.: 18/886,447

(22) Filed: Sep. 16, 2024

(30) Foreign Application Priority Data
Dec. 6, 2023 (KR) 10-2023-0175018

(51) Int. Cl. H01L 23/00; H01L 25/18; H05K 1/18; H10B 80/00

(52) U.S. Cl. CPC H01L 24/05; H01L 24/08; H01L 24/32; H01L 24/16; H01L 24/73; H01L 24/80; H01L 25/18; H01L 2224/05005; H01L 2224/05111; H01L 2224/05541; H01L 2224/05647; H01L 2224/08145; H01L 2224/16225; H01L 2224/32145; H01L 2224/32225; H01L 2224/73204; H01L 2224/80895; H01L 2224/80896; H01L 2924/1431; H01L 2924/1436; H01L 2924/3512; H05K 1/181; H10B 80/00

(57) ABSTRACT

A semiconductor package includes a first semiconductor chip including a substrate, a second semiconductor chip disposed on the first semiconductor chip, a conductive connector disposed between the first and second semiconductor chips, wherein the conductive connector electrically connects the first and second semiconductor chips with each other and a bonding layer disposed between the first and second semiconductor chips, wherein the bonding layer bonds the first and second semiconductor chips with each other and covers an upper sidewall of the conductive connector. The first conductive connector includes a first conductive pattern disposed at a lower portion of a trench on the substrate and includes a first metal, a second conductive pattern extending on the first conductive pattern in a vertical direction substantially perpendicular to an upper surface of the substrate and extending through an upper portion of the first conductive pattern and including a second metal and a third conductive pattern disposed between the first and second conductive patterns and contacts the first and second conductive patterns and including both the first and second metals.

### CROSS-REFERENCE TO RELATED APPLICATION

This application claims priority under 35 U.S.C. § 119 to Korean Patent Application No. 10-2023-0175018, filed on Dec. 6, 2023 in the Korean Intellectual Property Office (KIPO), the contents of which are herein incorporated by reference in their entirety.

### 1. TECHNICAL FIELD

Example embodiments relate to a semiconductor package. More particularly, example embodiments relate to a semiconductor package including a plurality of stacked chips.

### 2. DISCUSSION OF THE RELATED ART

In a method of manufacturing a high bandwidth memory (HBM) package, a conductive bump and a bonding layer are formed between semiconductor chips and a heat treatment process is performed thereon. The bonding layer may flow easily so as to move in a horizontal direction to fill a space between the semiconductor chips. A portion of the conductive bump including a metal having a low melting point, such as solder, may also flow easily during the heat treatment process so as to move in the horizontal direction by the bonding layer. Accordingly, an electrical short may occur between the conductive bump, and the conductive bump and a conductive pad of each of the semiconductor chips, if they are not bonded well and cracks may be formed therein.

### SUMMARY

According to example embodiments, there is provided a semiconductor package. The semiconductor package may include a first semiconductor chip including a substrate, a second semiconductor chip disposed on the first semiconductor chip, a conductive connector disposed between the first and second semiconductor chips, wherein the conductive connector electrically connects the first and second semiconductor chips with each other and a bonding layer disposed between the first and second semiconductor chips, wherein the bonding layer bonds the first and second semiconductor chips with each other and covers an upper sidewall of the conductive connector. The first conductive connector includes a first conductive pattern disposed at a lower portion of a trench on the substrate and includes a first metal, a second conductive pattern extending on the first conductive pattern in a vertical direction substantially perpendicular to an upper surface of the substrate and extending through an upper portion of the first conductive pattern and including a second metal and a third conductive pattern disposed between the first and second conductive patterns and contacts the first and second conductive patterns and including both the first and second metals.

According to example embodiments, there is provided a semiconductor package. The semiconductor package may include a buffer die, memory dies sequentially stacked on the buffer die, wherein each of the memory dies includes a substrate and a through electrode penetrating the substrate, a conductive connector disposed between the memory dies and electrically connecting the memory dies with each other, a bonding layer disposed between the memory dies, wherein the bonding layer bonds the memory dies with each other and at least partially surrounds a sidewall of the conductive connector and a molding disposed on the buffer die covering sidewalls of the memory dies. The conductive connector includes a first conductive pattern disposed at a lower portion of a trench on the substrate, the trench exposing an upper surface of the through electrode, and the first conductive pattern contacting the upper surface of the through electrode and a second conductive pattern extending on the first conductive pattern along a vertical direction substantially perpendicular to an upper surface of the substrate and extending through an upper portion of the first conductive pattern.

According to example embodiments, there is provided a semiconductor package. The semiconductor package may include a buffer die including a first substrate and a first through electrode penetrating the first substrate in a vertical direction, memory dies sequentially stacked on the buffer die, wherein each of the memory dies includes a second substrate and a second through electrode penetrating the second substrate in the vertical direction, a first conductive connector disposed between the buffer die and a lowermost one of the memory dies, wherein the first conductive connector electrically connects the buffer die and the lowermost one of the memory dies with each other, a first bonding layer between the buffer die and the lowermost one of the memory dies, wherein the first bonding layer bonds the buffer die and the lowermost one of the memory dies with each other and at least partially covers a sidewall of the first conductive connector, a second conductive connector disposed between the memory dies, wherein the second conductive connector electrically connects the memory dies with each other, a second bonding layer disposed between the memory dies, wherein the second bonding layer bonds the memory dies with each other and covers a sidewall of the second conductive connector and a molding disposed on the buffer die, wherein the molding covers sidewalls of the memory dies. The second conductive connector includes a first conductive pattern extending through an upper portion of the second substrate and contacting an upper surface of the second through electrode and a second conductive pattern extending on the first conductive pattern in the vertical direction, the second conductive pattern extending through an upper portion of the first conductive pattern.

### BRIEF DESCRIPTION OF THE DRAWINGS

A more complete appreciation of the present disclosure and many of the attendant aspects thereof will be readily obtained as the same becomes better understood by reference to the following detailed description when considered in connection with the accompanying drawings, wherein:

FIG. 1 is a cross-sectional view illustrating a semiconductor package in accordance with example embodiments, and FIGS. 2 and 3 are enlarged cross-sectional views of regions X and Y, respectively, of FIG. 1.

FIGS. 4, 5, 6, 7, 8, 9, 10, 11, 12 and 13 are cross-sectional views illustrating a method of manufacturing a semiconductor package in accordance with example embodiments.

FIGS. 14, 15, 16, 17 and 18 are cross-sectional views illustrating semiconductor packages in accordance with example embodiments, which may correspond to FIG. 3.

FIG. 19 is a cross-sectional view illustrating an electronic device in accordance with example embodiments.

### DETAILED DESCRIPTION OF EXAMPLE EMBODIMENTS

Hereinafter, example embodiments will be explained in detail with reference to the accompanying drawings. Hereinafter, a direction substantially parallel to an upper surface of a wafer or a substrate may be referred to as a horizontal direction, and a direction substantially perpendicular to the upper surface of the wafer or the substrate may be referred to as a vertical direction.

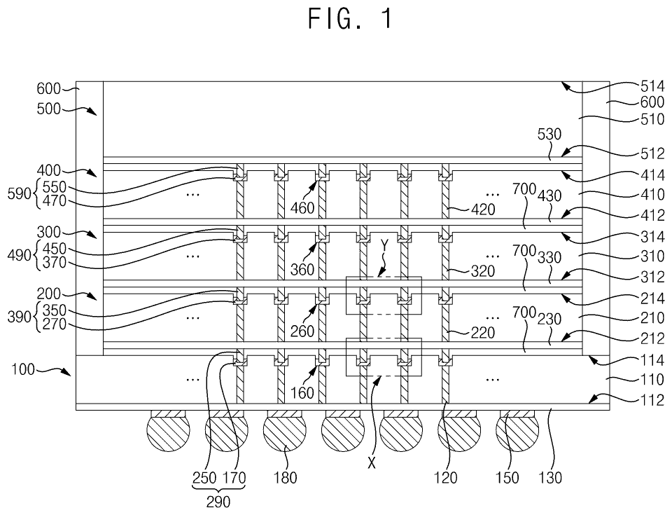

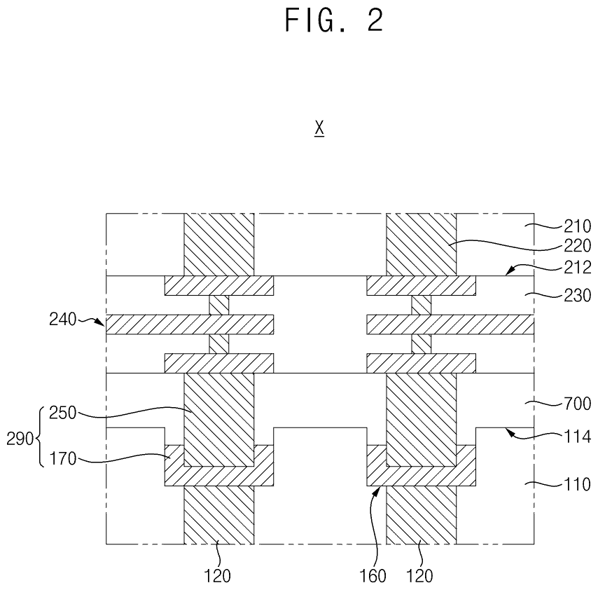

FIG. 1 is a cross-sectional view illustrating a semiconductor package in accordance with example embodiments, and FIGS. 2 and 3 are enlarged cross-sectional views of regions X and Y, respectively, of FIG. 1.

Referring to FIGS. 1 to 3, the semiconductor package may include a first semiconductor chip 100, second to fifth semiconductor chips 200, 300, 400 and 500 sequentially stacked on the first semiconductor chip 100, a bonding layer 700 disposed between the first to fifth semiconductor chips 100, 200, 300, 400 and 500, first to fifth conductive connectors 290, 390, 490, 590 and 180, and a molding 600 disposed on the first semiconductor chip 100 and covering sidewalls of the second to fifth semiconductor chips 200, 300, 400 and 500.

FIGS. 1 to 3 show that the semiconductor package includes five semiconductor chips 100, 200, 300, 400 and 500, however, the inventive concept may not necessarily be limited thereto, and the semiconductor package may include more than five semiconductor chips, e.g., eight or sixteen semiconductor chips. In example embodiments of the present invention, the semiconductor package may be a high bandwidth memory (HBM) package.

In example embodiments of the present invention, the first semiconductor chip 100 may be a buffer die and may include a logic device such as a controller. Each of the second to fifth semiconductor chips 200, 300, 400 and 500 may be a core die, and may include a volatile memory device such as Dynamic Random Access Memory (DRAM) device, Static Random Access Memory (SRAM) device, etc., or a non-volatile memory device such as flash memory device, Electrically Erasable Programmable Read-Only Memory (EEPROM) device, etc.

The first semiconductor chip 100 may include a first substrate 110 having first and second surfaces 112 and 114 opposite to each other along the vertical direction, a first through electrode 120 penetrating the first substrate 110, a first insulating interlayer and a second insulating interlayer 130 sequentially stacked along the vertical direction beneath the first surface 112 of the first substrate 110, a first conductive pad 150 disposed beneath the second insulating interlayer 130, a first trench 160 disposed on the second surface 114 of the first substrate 110, and a first conductive pattern 170 disposed at a lower portion of the first trench 160.

The first substrate 110 may include a semiconductor material such as silicon, germanium, silicon-germanium, or a III-V group compound semiconductor such as gallium phosphide (GaP), gallium arsenide (GaAs), gallium antimonide (GaSb), etc. In example embodiments of the present invention, the first substrate 110 may be a silicon-on-insulator (SOI) substrate or a germanium-on-insulator (GOI) substrate.

A circuit device such as a logic device may be formed beneath the first surface 112 of the first substrate 110. The circuit device may include circuit patterns, which may be at least partially covered by the first insulating interlayer.

The second insulating interlayer 130 may contain a first wiring structure therein. The first wiring structure may include elements such as wirings, vias, contact plugs, etc.

The first conductive pad 150 may be disposed under the second insulating interlayer 130, and may contact the first wiring structure to be electrically connected thereto. In example embodiments of the present invention, a plurality of first conductive pads 150 may be spaced apart from each other along the horizontal direction.

The first through electrode 120 may penetrate the first substrate 110 in the vertical direction. For example, the first substrate 110 may at least partially surround side surfaces of the first through electrode 120. A plurality of first through electrodes 120 may be spaced apart from each other along the horizontal direction. The first through electrode 120 may have a shape such as a circle, an ellipse, a polygon, a polygon with rounded corners, etc., in a plan view.

In an example embodiment of the present invention, the first through electrode 120 may penetrate the first substrate 110 and the first insulating interlayer and contact the first wiring structure and may be electrically connected to the first conductive pad 150 by the first wiring structure.

In some embodiments, the first through electrode 120 may penetrate the first substrate 110, the first insulating interlayer and the second insulating interlayer 130 and contact the first conductive pad 150 and may be electrically connected thereto. In some embodiments, the first through electrode 120 may penetrate the first substrate 110 and contact one of the circuit patterns included in the circuit device which is at least partially covered by the first insulating interlayer, and may be electrically connected to the first conductive pad 150 by the one of the circuit patterns and the first wiring structure.

The first trench 160 may penetrate an upper portion of the first through electrode 120 disposed in the first substrate 110 and a portion of the first substrate 110 adjacent to the first through electrode 120 along the horizontal direction. The first trench 160 may have a shape such as a circle, an ellipse, a polygon, a polygon with rounded corners, etc., in a plan view. In example embodiments of the present invention, a width measured along the horizontal direction of the first trench 160 may be about one to two times a width measured along the horizontal direction of the first through electrode 120.

The first conductive pattern 170 may be formed in the lower portion of the first trench 160. For example, an upper surface of the first conductive pattern 170 may be disposed at a lower level than the second surface 114 of the first substrate 110. For example, the upper surface of the first conductive pattern 170 may be disposed at a lower level than an uppermost surface of a portion of the first substrate 110 on which the first trench 160 is not formed. In example embodiments of the present invention, a width measured along the horizontal direction of the first conductive pattern 170 may be about one to two times the width measured along the horizontal direction of the first through electrode 120.

The first conductive pad 150 may include a metal such as aluminum, copper, nickel, etc. Each of the first insulating interlayer and the second insulating interlayer 130 may include, for example, silicon oxide or a low-k dielectric material such as an oxide doped with carbon or fluorine. As used herein, the term “low-k” may be understood to mean a material having a dielectric constant that is lower than that of silicon oxide.

In example embodiments of the present invention, the first conductive pattern 170 may include a metal having a low melting point or an alloy having a low melting point such as solder with a melting point of 200° C. or less. Thus, the first conductive pattern 170 may include a metal such as tin, or an alloy such as tin/silver, tin/copper, tin/indium, tin/silver/copper, etc.

The first through electrode 120 and the wirings, vias and the contact plugs of the first wiring structure may include materials such as a metal, a metal nitride, a metal silicide, etc.

The second semiconductor chip 200 may include a second substrate 210 having first and second surfaces 212 and 214 opposite to each other along the vertical direction, a second through electrode 220 penetrating the second substrate 210, a third insulating interlayer and a fourth insulating interlayer 230 sequentially stacked along the vertical direction beneath the first surface 212 of the second substrate 210, a second conductive pattern 250 disposed beneath the fourth insulating interlayer 230, a second trench 260 disposed on the second surface 214 of the second substrate 210, and a third conductive pattern 270 disposed at a lower portion of the second trench 260.

The second substrate 210 may include a semiconductor material such as silicon, germanium, silicon-germanium, or a III-V group compound semiconductor such as GaP, GaAs, GaSb, etc. In example embodiments of the present invention, the second substrate 210 may be a silicon-on-insulator (SOI) substrate or a germanium-on-insulator (GOI) substrate.

A circuit device, e.g., a volatile memory device such as a DRAM device, an SRAM device, etc., or a non-volatile memory device such as a flash memory device, an EEPROM device, etc., may be formed beneath the first surface 212 of the second substrate 210. The circuit device may include circuit patterns, which may be at least partially covered by the third insulating interlayer.

The fourth insulating interlayer 230 may contain a second wiring structure 240 therein. The second wiring structure 240 may include elements such as wirings, vias, contact plugs, etc. FIG. 2 shows that the second wiring structure 240 includes wirings including three levels, respectively, and vias including two levels, respectively, however, the inventive concept might not be necessarily limited thereto.

The second through electrode 220 may penetrate the second substrate 210 in the vertical direction. For example, the second substrate 210 may at least partially surround side surfaces of the second through electrode 220. A plurality of second through electrodes 220 may be spaced apart from each other along the horizontal direction. The second through electrode 220 may have a shape such as a circle, an ellipse, a polygon, a polygon with rounded corners, etc., in a plan view.

In an example embodiment of the present invention, the second through electrode 220 may penetrate the second substrate 210 and the third insulating interlayer and contact the second wiring structure 240 in the fourth insulating interlayer 230, which is shown in FIG. 2. In some embodiments, the second through electrode 220 may penetrate the second substrate 210, the third insulating interlayer and the fourth insulating interlayer 230. In some embodiments, the second through electrode 220 may penetrate the second substrate 210 and contact one of the circuit patterns included in the circuit device at least partially covered by the third insulating interlayer, and may be electrically connected to the second wiring structure 240 by the one of the circuit patterns.

The second conductive pattern 250 may be disposed beneath the fourth insulating interlayer 230 and may contact a portion of the second wiring structure 240 and be electrically connected thereto. In example embodiments of the present invention, a plurality of second conductive patterns 250 may be spaced apart from each other along the horizontal direction and may overlap corresponding ones of the first and second through electrodes 120 and 220, respectively.

In an example embodiment of the present invention, a width of the second conductive pattern 250 measured along the horizontal direction may be substantially the same as that of each of the first and second through electrodes 120 and 220. The second conductive pattern 250 may have a shape of a pillar extending in the vertical direction and may have a shape of a circle, an ellipse, a polygon, a polygon with rounded corners, etc., in a plan view.

The second trench 260 may penetrate an upper portion of the second through electrode 220 in the second substrate 210 and a portion of the second substrate 210 adjacent to the second through electrode 220 along the horizontal direction. In example embodiments of the present invention, a width measured along the horizontal direction of the second trench 160 may be about one to two times a width measured along the horizontal direction of the second through electrode 220.

The third conductive pattern 270 may be formed in the lower portion of the second trench 260. For example, an upper surface of the third conductive pattern 270 may be disposed at a lower level than the second surface 214 of the second substrate 210. For example, the upper surface of the third conductive pattern 270 may be disposed at a lower level than an uppermost surface of a portion of the second substrate 100 on which the second trench 260 is not formed.

In example embodiments of the present invention, a width measured along the horizontal direction of the third conductive pattern 270 may be about one to two times the width measured along the horizontal direction of the second through electrode 220.

In example embodiments of the present invention, the first conductive pattern 170 at the lower portion of the first trench 160 of the first semiconductor chip 100 and the second conductive pattern 250 of the second semiconductor chip 200 may contact each other and form the first conductive connector 290. The second conductive pattern 250 may extend through an upper portion of the first conductive pattern 170, and thus the first conductive pattern 170 may at least partially cover a lower surface and a lower sidewall of the second conductive pattern 250.

The first conductive connector 290 may contact the first through electrode 120 of the first semiconductor chip 100 and the second wiring structure 240 of the second semiconductor chip 200. Thus, the first and second semiconductor chips 100 and 200 may be electrically connected to each other through the first conductive connector 290.

The bonding layer 700 may be interposed between the fourth insulating interlayer 230 in the second semiconductor chip 200 and the second surface 114 of the first substrate 110 in the first semiconductor chip 100, and fill a space therebetween. The bonding layer 700 may at least partially cover an upper sidewall of the second conductive pattern 250 and an upper surface of the first conductive pattern 170. The bonding layer 700 may include a non-conductive film (NCF) such as thermosetting resin.

In example embodiments of the present invention, the second conductive pattern 170 may include a metal having a high melting point or an alloy having a high melting point. As used herein, the phrase “high melting point” is intended to mean a melting point over a particular level such as, for example 1000° C. such as copper. For example, the second conductive pattern 170 may include a metal such as copper, aluminum, nickel, titanium, etc., or an alloy such as titanium/copper, nickel/gold, titanium/palladium, titanium/nickel, chromium/copper, etc.

The third insulating interlayer and the fourth insulating interlayer 230 may include, for example, silicon oxide or a low-k dielectric material such as an oxide doped with carbon or fluorine.

In example embodiments of the present invention, the third conductive pattern 270 may include a metal having a low melting point or an alloy having a low melting point such as solder. For example, the third conductive pattern 270 may include a metal such as tin, or an alloy such as tin/silver, tin/copper, tin/indium, tin/silver/copper, etc.

The second through electrode 220, and the wirings, vias and contact plugs included in the second wiring structure 240 may include a conductive material such as a metal, a metal nitride, a metal silicide, etc.

The third to fifth semiconductor chips 300, 400 and 500 may be sequentially stacked on the second semiconductor chip 200, and the bonding layer 700 may be interposed therebetween. For example, the bonding layer 700 may be disposed between the third semiconductor chip 300 and the fourth semiconductor chip 400, and between the fourth semiconductor chip 400 and the fifth semiconductor chip 500.

As the first conductive connector 290 covered by the bonding layer 700 is disposed between the first and second semiconductor chips 100 and 200, the second to fourth conductive connectors 390, 490 and 590 covered by the bonding layer 700 may be interposed between the second to fifth semiconductor chips 200, 300, 400 and 500, and may electrically connect the second to fifth semiconductor chips 200, 300, 400 and 500 to each other.

Each of the third to fifth semiconductor chips 300, 400 and 500 may have a structure substantially the same as or similar to that of the second semiconductor chip 200.

The third semiconductor chip 300 may include a third substrate 310 having first and second surfaces 312 and 314 opposite to each other in the vertical direction, and a fifth insulating interlayer and a sixth insulating interlayer 330 sequentially stacked along the vertical direction beneath the first surface 312 of the third substrate 310. A third through electrode 320 may extend in the vertical direction through the third substrate 310, and a third wiring structure 340 may be formed in the sixth insulating interlayer 330. Additionally, a fourth conductive pattern 350 may be formed beneath the sixth insulating interlayer 330, a third trench 360 may be formed on the second surface 314 of the third substrate 310, and a fourth conductive pattern 370 may be formed at a lower portion of the third trench 360.

The third conductive pattern 270 disposed at the lower portion of the second trench 260 in the second semiconductor chip 200 and the fourth conductive pattern 350 in the third semiconductor chip 300 may contact each other and form a second conductive connector 390. The fourth conductive pattern 350 may extend through an upper portion of the third conductive pattern 270, and the third conductive pattern 270 may at least partially cover a lower surface and a lower sidewall of the fourth conductive pattern 350.

The fourth semiconductor chip 400 may include a fourth substrate 410 having first and second surfaces 412 and 414 opposite to each other in the vertical direction, and a seventh insulating interlayer and an eighth insulating interlayer 430 sequentially stacked along the vertical direction beneath the first surface 412 of the fourth substrate 410. For example, the fourth substrate 410 may be interposed between the first and second surfaces 412 and 414. A fourth through electrode 420 may extend in the vertical direction through the fourth substrate 410, and a fourth wiring structure may be formed in the eighth insulating interlayer 430. Additionally, a sixth conductive pattern 450 may be formed beneath the eighth insulating interlayer 430, a fourth trench 460 may be formed on the second surface 414 of the fourth substrate 410, and a seventh conductive pattern 470 may be formed at a lower portion of the fourth trench 460.

The fifth conductive pattern 370 disposed at the lower portion of the third trench 360 in the third semiconductor chip 300 and the sixth conductive pattern 450 in the fourth semiconductor chip 400 may contact each other and form a third conductive connector 490. The sixth conductive pattern 450 may extend through an upper portion of the fifth conductive pattern 370, and the fifth conductive pattern 370 may at least partially cover a lower surface and a lower sidewall of the sixth conductive pattern 450. As used herein, the phrase “at least partially covering” may mean that the first element covers some or all of the second element.

The fifth semiconductor chip 500 may include a fifth substrate 510 having first and second surfaces 512 and 514 opposite to each other in the vertical direction, and a ninth insulating interlayer and a tenth insulating interlayer 530 sequentially stacked in the vertical direction beneath the first surface 512 of the fifth substrate 510. A fifth wiring structure may be formed in the tenth insulating interlayer 530. Additionally, an eighth conductive pattern 550 may be formed beneath the tenth insulating interlayer 530.

The seventh conductive pattern 470 disposed at the lower portion of the fourth trench 460 in the fourth semiconductor chip 400 and the eighth conductive pattern 550 in the fifth semiconductor chip 500 may contact each other and form a fourth conductive connector 590. The eighth conductive pattern 550 may extend through an upper portion of the seventh conductive pattern 470, and the seventh conductive pattern 470 may at least partially cover a lower surface and a lower sidewall of the eighth conductive pattern 550.

Each of the third to fifth substrates 310, 410 and 510 may include a semiconductor material such as silicon, germanium, silicon-germanium, or a III-V group compound semiconductor such as GaP, GaAs, GaSb, etc. In example embodiments of the present invention, each of the third to fifth substrates 310, 410 and 510 may be a silicon-on-insulator (SOI) substrate or a germanium-on-insulator (GOI) substrate.

A circuit device, for example, a volatile memory device such as a DRAM device, an SRAM device, etc., or a non-volatile memory device such as a flash memory device, an EEPROM device, etc., may be formed beneath each of the first surfaces 312, 412 and 512 of the third to fifth substrates 310, 410 and 510. The circuit device may include circuit patterns, which may be at least partially covered by each of the fifth, seventh and ninth insulating interlayers.

The first to fifth semiconductor chips 100, 200, 300, 400 and 500 may be electrically connected to each other by the first to fourth through electrodes 120, 220, 320 and 420 penetrating the first to fourth substrates 110, 210, 310 and 410, respectively, the first wiring structure, the second and third wiring structures 240 and 340, and the fourth and fifth wiring structures electrically connected thereto, the first to fourth conductive connectors 290, 390, 490 and 590 electrically connected thereto, and electrical signals such as data signals, control signals, etc., may be transferred to each other. In example embodiments of the present invention, the first to fourth conductive connectors 290, 390, 490 and 590 may overlap the first to fourth through electrodes 120, 220, 320 and 420 along the vertical direction.

The molding 600 may at least partially cover sidewalls of the second to fifth semiconductor chips 200, 300, 400 and 500 disposed on the first semiconductor chip 100. An upper surface of the molding 600 may be substantially coplanar with an upper surface of the fifth semiconductor chip 500. The molding 600 may include a polymer, such as epoxy molding compound (EMC).

The fifth conductive connector 180 may contact a lower surface of the first conductive pad 150 in the first semiconductor chip 100. For example, an upper surface of the fifth conductive connector 180 may be in contact with the lower surface of the first conductive pad 150 in the first semiconductor chip 100. The fifth conductive connector 180 may be a conductive bump including, for example, solder.

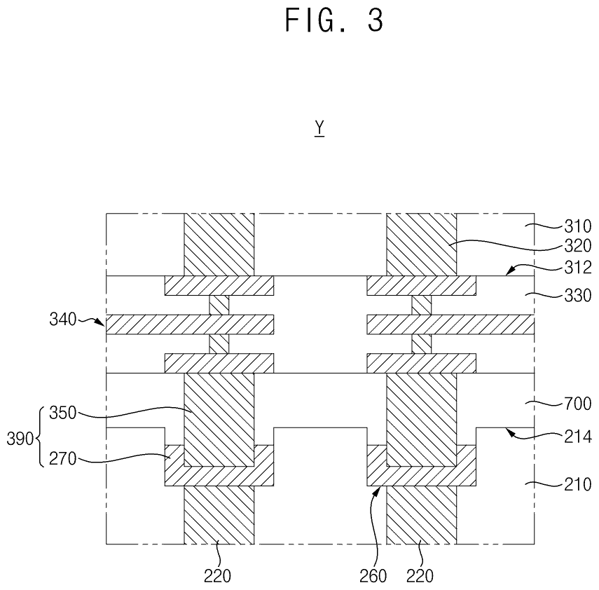

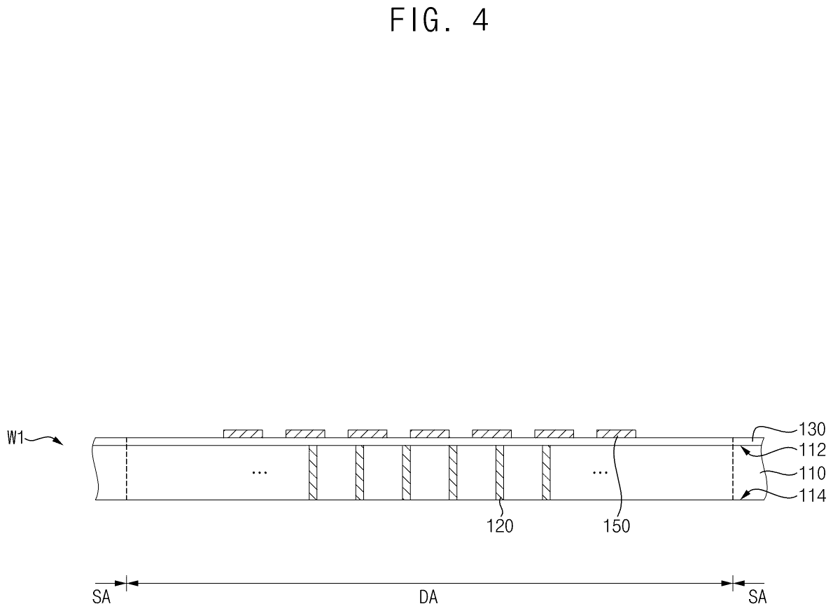

As illustrated below with reference to FIGS. 4 to 13, each of the first to fourth conductive connectors 290, 390, 490 and 590 may be formed with no crack therein, and may be electrically connected to the first to fourth through electrodes 120, 220, 320 and 420, respectively, and electrical short might not occur between neighboring ones of the first to fourth conductive connectors 290, 390, 490 and 590 along the horizontal direction.

For example, in the second conductive connector 390, the third conductive pattern 270 may have a width greater than those of the fourth conductive pattern 350 and the second through electrode 220 and may at least partially cover the lower surface and the lower sidewall of the fourth conductive pattern 350. Thus, the electrical connection between the third and fourth conductive patterns 270 and 350 may be good and may be electrically connected to the second through electrode 220 well. Additionally, each of the third conductive patterns 270 included in the second conductive connectors 390, respectively, neighboring along the horizontal direction may be formed in the second trench 260. For example, the second conductive connectors 390 may be spaced apart from each other along the horizontal direction. The upper surface of each of the third conductive patterns 270 may be disposed at a lower level than the second surface 214 of the second substrate 210. Accordingly, the third conductive patterns 270 neighboring in the horizontal direction might not be electrically connected to each other, and the electrical short between the second conductive connectors 390 may be prevented.

As a result, the semiconductor package including the first to fourth conductive connectors 290, 390, 490 and 590 may have enhanced electrical characteristics.

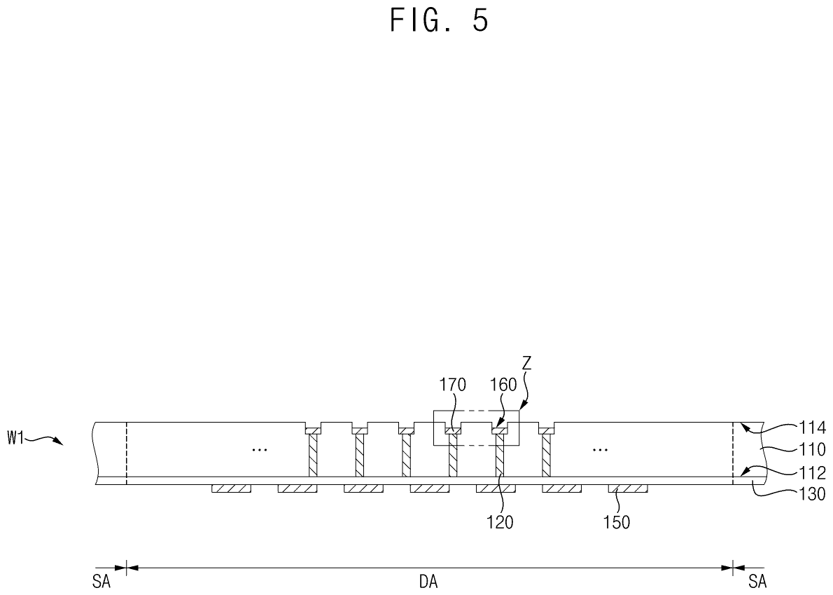

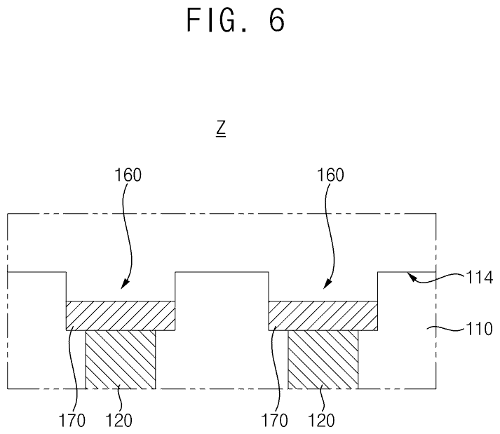

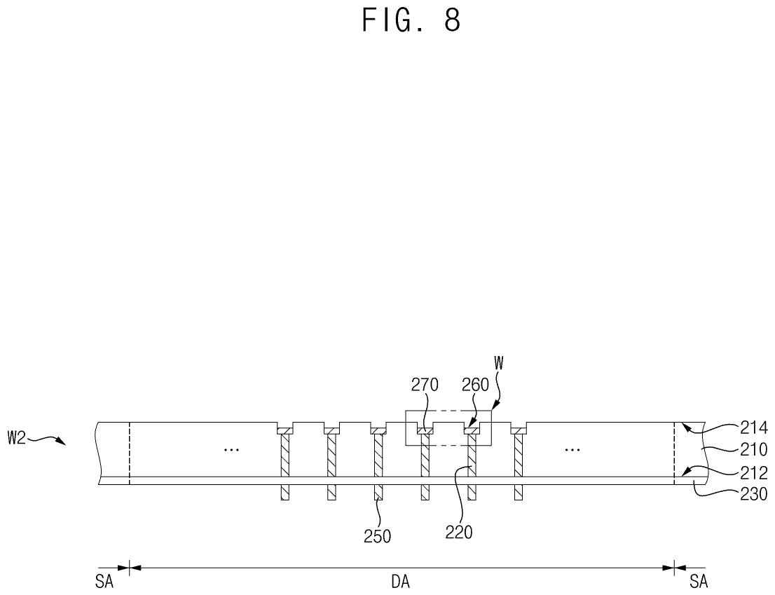

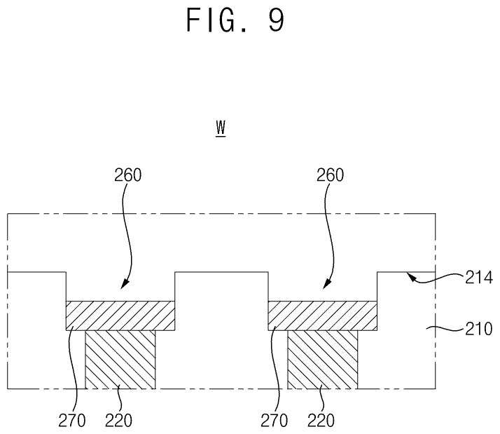

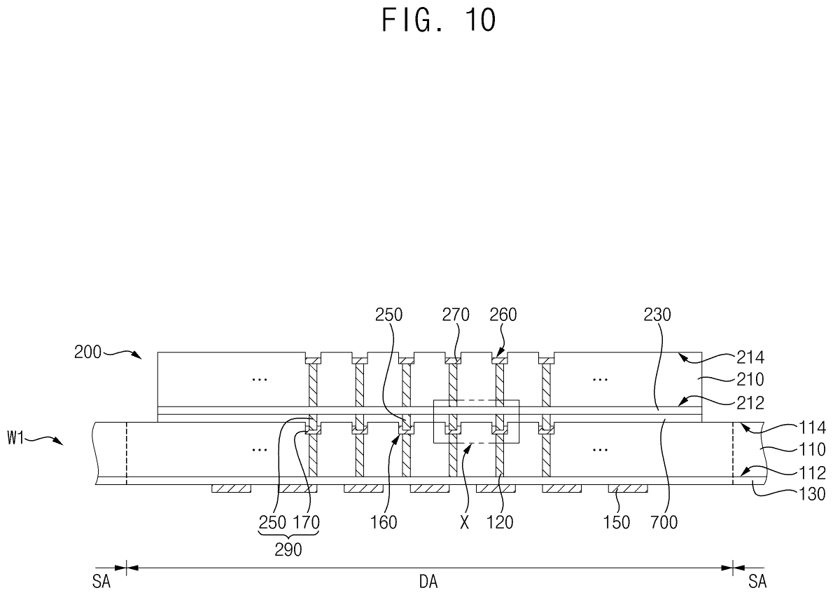

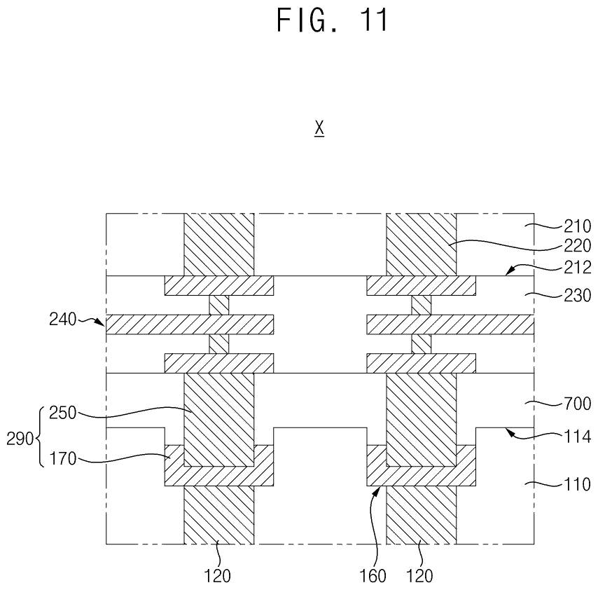

FIGS. 4 to 13 are cross-sectional views illustrating a method of manufacturing a semiconductor package in accordance with example embodiments. FIG. 6 is an enlarged cross-sectional view of region Z of FIG. 5, FIG. 9 is an enlarged cross-sectional view of region W of FIG. 8, and FIG. 11 is an enlarged cross-sectional view of region X of FIG. 10.

Referring to FIG. 4, a first wafer W1 may be provide.

In example embodiments of the present invention, the first wafer W1 may include a first substrate 110 having first and second surfaces 112 and 114 opposite to each other in the vertical direction. Additionally, the first wafer W1 may include a plurality of die regions DA and a scribe lane region SA surrounding each of the die regions DA. For example, the die region DA may be interposed between the scribe lane regions SA. The first wafer W1 may be cut along the scribe lane region SA by a sawing process and be singulated into a plurality of first semiconductor chips.

In the die region DA, a circuit device may be formed on the first surface 112 of the first substrate 110. The circuit device may include a logic device. The circuit device may include circuit patterns, and a first insulating interlayer may be formed on the first surface 112 of the first substrate 110 and at least partially cover the circuit patterns. A second insulating interlayer 130 may be formed on the first insulating interlayer, and may contain a first wiring structure therein.

A first conductive pad 150 may be formed on second insulating interlayer 130 and contact the first wiring structure. A first conductive pad 150 may be electrically connected to the first wiring structure.

A through electrode 120 may be formed through the first substrate 110 in the vertical direction. For example, the through electrode 120 may penetrate the first substrate 110. In example embodiments of the present invention, a plurality of first through electrodes 120 may be spaced apart from each other along the horizontal direction.

Referring to FIGS. 5 and 6, after overturning the first wafer W1, a portion of the first through electrode 120 adjacent to the second surface 114 of the first substrate 110 and a portion of the first substrate 110 adjacent to the portion of the first through electrode 120 in the horizontal direction may be removed by, for example, a dry etching process.

Thus, a first trench 160 may be formed on a portion of the first substrate 110 adjacent to the second surface 114 of the first substrate 110 and may expose an upper surface of the first through electrode 120. In example embodiments of the present invention, a width measured along the horizontal direction of the first trench 160 may be about one to two times a width measured the horizontal direction of an upper surface of the first through electrode 120.

A first conductive pattern 170 may be formed at a lower portion of the first trench 160.

In an example embodiment of the present invention, the first conductive pattern 170 may be formed by forming a first conductive layer on the upper surfaces of the first through electrode 120 and the portion of the first substrate 110 adjacent thereto, a sidewall of the first trench 160 and the second surface 114 of the first substrate 110 through a deposition process, such as a chemical vapor deposition (CVD), atomic layer deposition (ALD) or a physical deposition process, forming a first photoresist pattern to cover a portion of the first conductive layer in the first trench 160, performing a dry etching process using the first photoresist pattern as an etching mask to remove a portion of the first photoresist pattern on the second surface 114 of the first substrate 110, removing the first photoresist pattern, and removing an upper portion of the first conductive layer on the sidewall of the first trench 160 through, for example, an etch back process.

In some embodiments, the first conductive pattern 170 may be formed by forming a seed conductive layer on the upper surfaces of the first through electrode 120 and the portion of the first substrate 110 adjacent thereto, a sidewall of the first trench 160 and the second surface 114 of the first substrate 110 through a deposition process, forming a second photoresist pattern to cover a portion of the seed layer in the first trench 160, performing an electroplating process or an electroless plating process to form a first conductive layer in the first trench 160, removing the second photoresist pattern and a portion of the seed layer under the second photoresist pattern, and removing an upper portion of the first conductive layer and an upper portion of the seed layer on the sidewall of the first trench 160 through, for example, an etch back process.

In some embodiments, the first conductive pattern 170 may be formed by forming a third photoresist pattern on the second surface 114 of the first substrate 110, forming a first conductive layer on the upper surfaces of the first through electrode 120 and the portion of the first substrate 110 adjacent thereto, a sidewall of the first trench 160 and a sidewall and an upper surface of the third photoresist pattern through a deposition process, performing a wet etching process to remove a portion of the first conductive layer on the second surface 114 of the first substrate 110 and the third photoresist pattern, and removing an upper portion of the first conductive layer on the sidewall of the first trench 160 through, for example, an etch back process.

In example embodiments of the present invention, the first conductive pattern 170 may include a metal having a low melting point or an alloy having a low melting point such as solder.

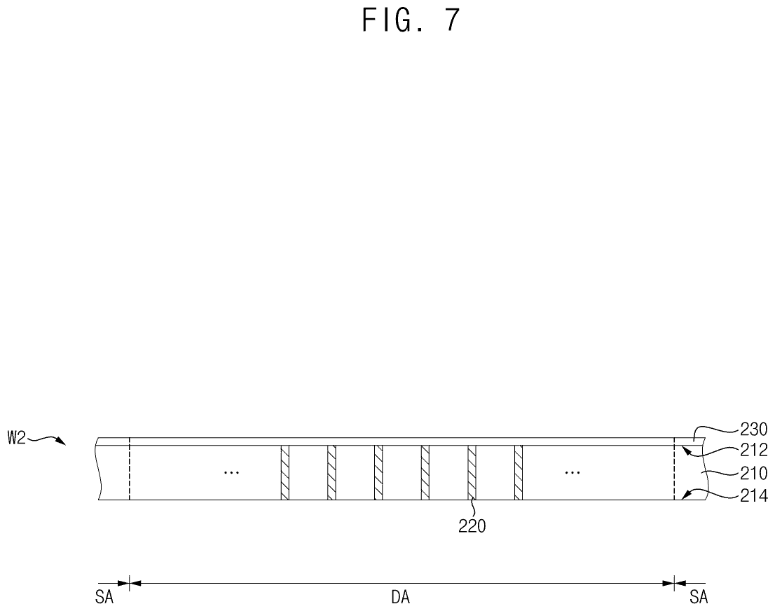

Referring to FIG. 7, a second wafer W2 may be provide.

In example embodiments of the present invention, the second wafer W2 may include a second substrate 210 having first and second surfaces 212 and 214 opposite to each other in the vertical direction. Additionally, the second wafer W2 may include a plurality of die regions DA and a scribe lane region SA surrounding each of the die regions DA. For example, the die region DA may be interposed between the scribe lane regions SA. The second wafer W2 may be cut along the scribe lane region SA by a sawing process and be singulated into a plurality of second semiconductor chips.

In the die region DA, a circuit device may be formed on the first surface 212 of the second substrate 210. The circuit device may include a memory device. The circuit device may include circuit patterns, and a third insulating interlayer may be formed on the first surface 212 of the second substrate 210 and may cover the circuit patterns.

A fourth insulating interlayer 230 may be formed on the third insulating interlayer, and may contain a second wiring structure 240 therein (refer to FIG. 11).

In example embodiments of the present invention, a second through electrode 220 extending through the second substrate 210 in the vertical direction may be formed. In example embodiments of the present invention, a plurality of second through electrodes 220 may be spaced apart from each other along the horizontal direction. In an example embodiment of the present invention, a width measured along the horizontal direction of the second through electrode 220 may be substantially the same as a width measured along the horizontal direction of the first through electrode 120.

Referring to FIGS. 8 and 9, a second conductive pattern 250 may be formed on the fourth insulating interlayer 230 and contact the second wiring structure 240.

In an example embodiment of the present invention, a plurality of second conductive patterns 250 may be spaced apart from each other along the horizontal direction, and may overlap the second through electrodes 220, respectively, along the vertical direction. In an example embodiment of the present invention, a width measured along the horizontal direction of the second conductive pattern 250 may be substantially the same as a width measured along the horizontal direction of the second through electrode 220. The second conductive pattern 250 may have a shape of a pillar extending along the vertical direction.

The second conductive pattern 250 may include a metal having a high melting point or an alloy having a high melting point.

Processes substantially the same as or similar to those illustrated with respect to FIGS. 5 and 6 may be performed.

After overturning the second wafer W2, a portion of the second through electrode 220 adjacent to the second surface 214 of the second substrate 210 and a portion of the second substrate 210 adjacent to the portion of the second through electrode 220 in the horizontal direction may be removed by, for example, a dry etching process and form a second trench 260 on a portion of the second substrate 210 adjacent to the second surface 214 of the second substrate 210 exposing an upper surface of the second through electrode 220. In example embodiments of the present invention, a width measured along the horizontal direction of the second trench 260 may be about one to two times a width measured along the horizontal direction of an upper surface of the second through electrode 220. A third conductive pattern 270 may be formed at a lower portion of the second trench 260.

Referring to FIGS. 10 and 11, after cutting the second wafer W2 along the scribe lane region SA by a sawing process into second semiconductor chips 200, a bonding layer 700 may be attached on each of the second semiconductor chips 200.

The bonding layer 700 may be formed on the fourth insulating interlayer 230 and at least partially cover the second conductive pattern 250. For example, the bonding layer 700 may at least cover side surfaces of the second conductive pattern 250. The bonding layer 700 may include a NCF such as thermosetting resin.

In some embodiments, the bonding layer 700 may be attached on the fourth insulating interlayer 230 of the second wafer W2 before the sawing process.

Each of the second semiconductor chips 200 may be mounted on the first wafer W1 such that the bonding layer 700 on each of the semiconductor chips 200 may contact the second surface 114 of the first substrate 110 included in the first wafer W1.

The second semiconductor chips 200 may be disposed on the respective die regions DA of the first wafer W1, and the second conductive pattern 250 of each of the second semiconductor chips 200 may overlap along the vertical direction the first trench 160 on the first substrate 110 included in the first wafer W1. In example embodiments of the present invention, the second conductive pattern 250 may overlap the first through electrode 120 in the first trench 160 along the vertical direction.

A thermal pressing process may be performed at a temperature equal to or less than about 400° C. so that the second semiconductor chips 200 may be bonded to the first wafer W1.

During the thermal pressing process, the first conductive pattern 170 having a low melting point in the lower portion of the first trench 160 may be melted and may flow easily, and the second conductive pattern 250 of the second semiconductor chip 200 may be inserted onto an upper portion of the first conductive pattern 170. Thus, the first and second conductive patterns 170 and 250 may contact each other in the first trench 160.

Additionally, during the thermal pressing process, the NCF included in the bonding layer 700 may also be melted and may flow easily. The NCF included in the bonding layer 700 may flow in a space between the fourth insulating interlayer 230 of the second semiconductor chip 200 and the second surface 114 of the first substrate 110 included in the first wafer W1.

However, the first trench 160 is formed on the second surface 114 of the first substrate 110. Thus, a portion of the bonding layer 700 may move into the first trench 150 so that an amount of movement of the bonding layer 700 in the horizontal direction may be reduced.

If the first conductive pattern 170 is formed on the second surface 114 of the first substrate 110 without the first trench 160, during the thermal pressing process, the bonding layer 700 might not move other than in the horizontal direction, and a portion of the first conductive pattern 170 may flow easily due to the low melting point may also move in the horizontal direction due to the horizontal movement of the bonding layer 700. Thus, electrical short may occur between neighboring ones of the first conductive patterns 170. Additionally, a portion of the first conductive pattern 170 may move in the horizontal direction so that an amount of a portion of the first conductive pattern 170 bonded to the second conductive pattern 250 may decrease. Accordingly, the electrical connection between the first and second conductive patterns 170 and 250 may be reduced, and crack may be generated between the first and second conductive patterns 170 and 250.

However, in example embodiments of the present invention, the first trench 160 may be formed on the second surface 114 of the first substrate 110 so as to weaken the horizontal movement of the bonding layer 700 during the thermal pressing process. Additionally, the first conductive pattern 170 may flow easily and may be formed in the first trench 160, so that a portion of the first conductive pattern 170 might not move in the horizontal direction due to the horizontal movement of the bonding layer 700. Accordingly, the electrical short between neighboring first conductive patterns 170 may be prevented, and the adhesion between the first and second conductive patterns 170 and 250 may increase and may prevent the crack.

In an example embodiment of the present invention, the width measured along the horizontal direction of the second conductive pattern 250 in the second semiconductor chip 200 may be substantially the same as the width measured along the horizontal direction of the first through electrode 120 in the first wafer W1 and the second through electrode 220 in the second semiconductor chip 200, and thus may be smaller than the width in the horizontal direction of the first trench 160. Accordingly, even if the second conductive pattern 250 is not aligned with the first through electrode 120 in the first trench 160, the electrical connection between the second conductive pattern 250 and the first through electrode 120 may be good, by the first conductive pattern 170 having an area greater than that of the second conductive pattern 250 and at least partially surrounding a lower portion of the second conductive pattern 250.

After the thermal pressing process, as a temperature of the bonding layer 700 decreases, the bonding layer 700 may solidify and be cured, and the bonding layer 700 may fill a space between the fourth insulating interlayer 230 and the second surface 114 of the first substrate 110 and at least partially surround upper portions of the second conductive patterns 250.

The first and second conductive patterns 170 and 250 stacked along the vertical direction between the first wafer W1 and the second semiconductor chip 200 may collectively form a first conductive connector 290. The second conductive pattern 250 may extend through an upper portion of the first conductive pattern 170, and the first conductive pattern 170 may at least partially cover a lower surface and a lower sidewall of the second conductive pattern 250.

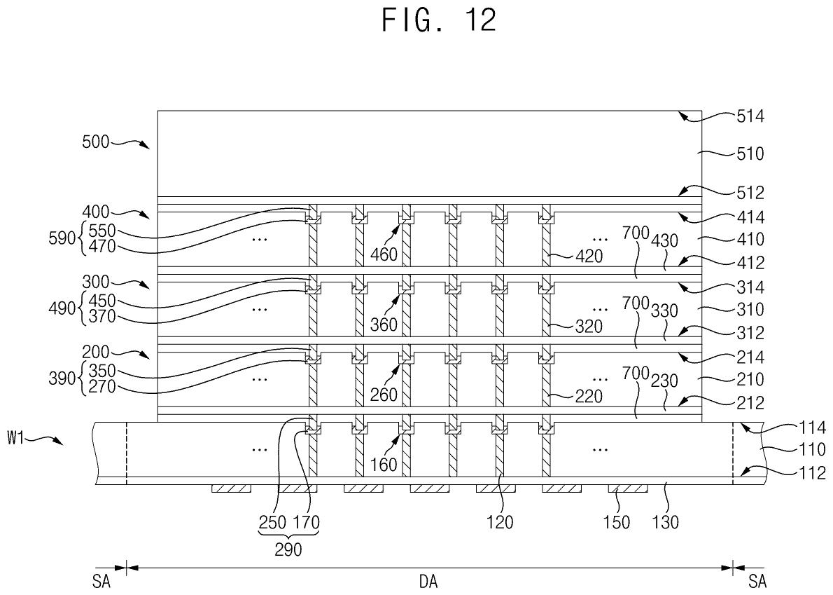

Referring to FIG. 12, third to fifth semiconductor chips 300, 400 and 500 may be sequentially stacked on the second semiconductor chip 200 along a vertical direction.

Processes substantially the same as or similar to those illustrated with respect to FIGS. 7 to 11 may be performed and form a plurality of third semiconductor chips 300. Processes substantially the same as or similar to those illustrated with respect to FIGS. 10 and 11 may be performed so that the third semiconductor chip 300 may be stacked on the second semiconductor chip 200.

In example embodiments of the present invention, the third semiconductor chip 300 may include a third substrate 310 having first and second surfaces 312 and 314 opposite to each other in the vertical direction, and a fifth insulating interlayer and a sixth insulating interlayer 330 stacked along the vertical direction beneath the first surface 312 of the third substrate 310. A third through electrode 320 penetrate the third substrate 310 along the vertical direction, and a third wiring structure 340 (refer to FIG. 3) may be formed in the sixth insulating interlayer 330. A fourth conductive pattern 350 may be formed beneath the sixth insulating interlayer 330, a third trench 360 may be formed on the second surface 314 of the third substrate 310, and a fifth conductive pattern 370 may be formed at a lower portion of the third trench 360.

After forming the bonding layer 700 to contact the sixth insulating interlayer 330 and cover the fourth conductive pattern 350, each of the third semiconductor chips 300 may be mounted on the second semiconductor chip 200 such that the bonding layer 700 attached to each of the third semiconductor chips 300 may contact the second surface 214 of the second substrate 210 included in the second semiconductor chip 200.

The fourth conductive pattern 350 in the third semiconductor chip 300 may overlap the second trench 260 on the second surface 214 of the second substrate 210 included in the second semiconductor chip 200 along the vertical direction. In example embodiments, the fourth conductive pattern 350 may overlap the second through electrode 220 in the second trench 260 along the vertical direction.

A thermal pressing process may be performed at a temperature equal to or less than about 400° C. so that each of the third semiconductor chips 200 may be bonded to the second semiconductor chip 200, and the fourth conductive pattern 350 may be inserted into an upper portion of the third conductive pattern 270 during the thermal pressing process. After the thermal pressing process, as a temperature of the bonding layer 700 decreases, the bonding layer 700 may solidify and be cured, and the bonding layer 700 may fill a space between the sixth insulating interlayer 330 and the second surface 214 of the second substrate 210 and at least partially surround upper portions of the fourth conductive patterns 350.

The third and fourth conductive patterns 270 and 350 stacked in the vertical direction between the second and third semiconductor chips 200 and 300 may collectively form a second conductive connector 390. The fourth conductive pattern 350 may extend through an upper portion of the third conductive pattern 270, and the third conductive pattern 270 may at least partially cover a lower surface and a lower sidewall of the fourth conductive pattern 350.

Likewise, fourth and fifth semiconductor chips 400 and 500 may be sequentially stacked on the third semiconductor chip 300 along the vertical direction.

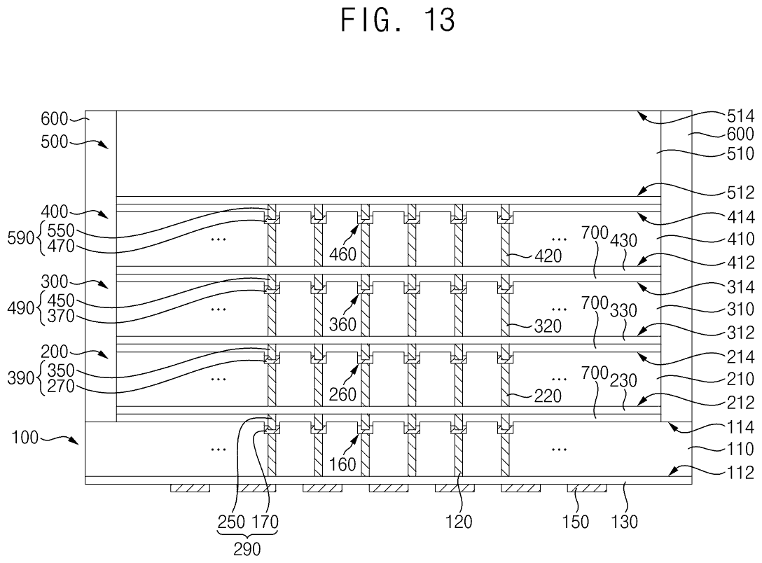

Referring to FIG. 13, a molding 600 may be formed on the first wafer W1 and fill a space between structures each of which may include the second to fifth semiconductor chips 200, 300, 400 and 500.

In example embodiments of the present invention, the molding 600 may expose an upper surface of the fifth semiconductor chip 500.

Referring to FIGS. 1 to 3 again, a fifth conductive connector 180 may be formed and contact a lower surface of the first conductive pad 150 beneath the second insulating interlayer 130 of the first wafer W1, and the first wafer W1 may be cut along the scribe lane region SA by, for example, a sawing process and be singulated into a plurality of first semiconductor chips 100.

During the sawing process, the molding 600 may also be cut and cover sidewalls of the second to fifth semiconductor chips 200, 300, 400 and 500 disposed on each of the first semiconductor chips 100.

The semiconductor package may be manufactured by the above processes.

As illustrated above, when the second to fifth semiconductor chips 200, 300, 400 and 500 are sequentially stacked on and bonded to the first wafer W1, the second, fourth, sixth and eighth conductive patterns 250, 350, 450 and 550 may be inserted into upper portions of the first, third, fifth and seventh conductive patterns 170, 270, 370 and 470 in the first to fourth trenches 160, 260, 360 and 460, respectively. Each of the first, third, fifth and seventh conductive patterns 170, 270, 370 and 470 may have a relatively low melting point, and thus may flow easily during the thermal pressing process. Accordingly, the first, third, fifth and seventh conductive patterns 170, 270, 370 and 470 may at least partially surround lower portions of the second, fourth, sixth and eighth conductive patterns 250, 350, 450 and 550, respectively.

The first, third, fifth and seventh conductive patterns 170, 270, 370 and 470 may have areas greater than those of the second, fourth, sixth and eighth conductive patterns 250, 350, 450 and 550, respectively. Thus, even if the second, fourth, sixth and eighth conductive patterns 250, 350, 450 and 550 are not exactly aligned with the first, third, fifth and seventh conductive patterns 170, 270, 370 and 470, the connection therebetween may be good, and the first to fourth through electrodes 120, 220, 320 and 420 may be electrically connected to each other.

During the thermal pressing process, the bonding layer 700 may flow easily and may move in the horizontal direction, however, a portion of the bonding layer 700 may flow into each of the first to fourth trenches 160, 260, 360 and 460 so that the horizontal movement of the bonding layer 700 may be restricted. Additionally, the horizontal movement of the first, third, fifth and seventh conductive patterns 170, 270, 370 and 470 may be restricted by the first to fourth trenches 160, 260, 360 and 460, respectively, and thus the electrical short between neighboring ones of the first, third, fifth and seventh conductive patterns 170, 270, 370 and 470 may be prevented.

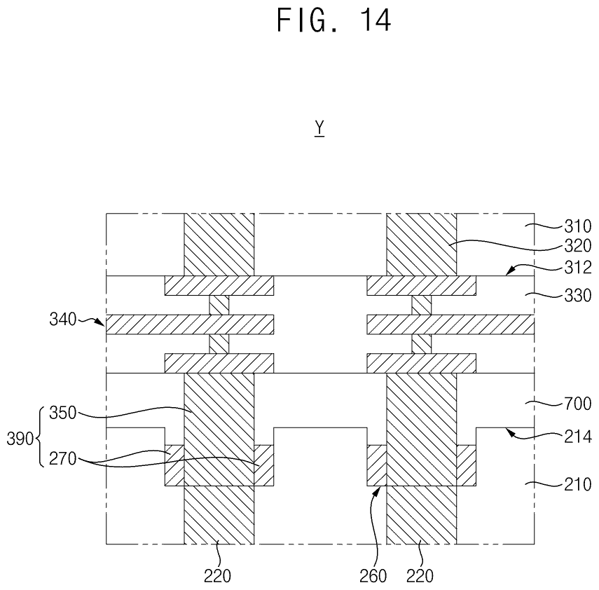

FIGS. 14 to 18 are cross-sectional views illustrating semiconductor packages in accordance with example embodiments, which may correspond to FIG. 3.

To the extent that an element has not been described in detail, it may be assumed that the element is at least similar to corresponding elements that have been described in FIGS. 1 to 3.

Hereinafter, the second conductive connector 390 is illustrated. Each of the first, third and fourth conductive connectors 290, 490 and 590 may have substantially the same structure as the second conductive connector 390.

Referring to FIG. 14, the third conductive pattern 270 included in the second conductive connector 390 may cover the lower sidewall of the fourth conductive pattern 350, but might not cover the lower surface of the fourth conductive pattern 350.

Thus, the fourth conductive pattern 350 may directly contact an upper surface of the second through electrode 220 and be electrically connected thereto.

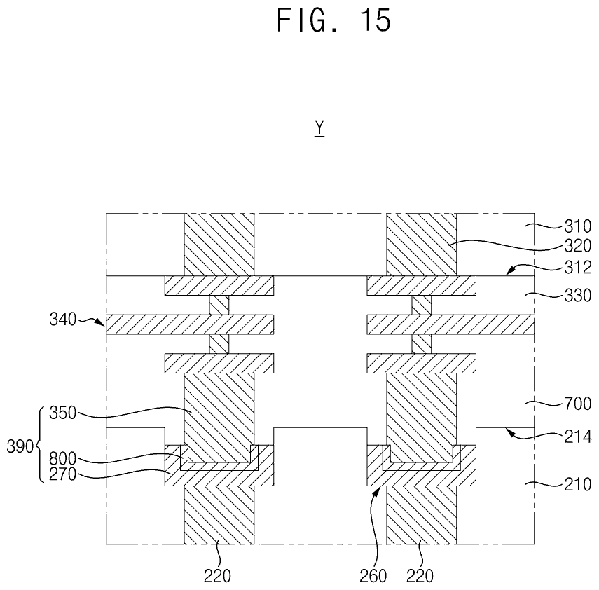

Referring to FIG. 15, the second conductive connector 390 may further include a ninth conductive pattern 800.

The ninth conductive pattern 800 may be formed at an interface between the third and fourth conductive patterns 270 and 350, and may include both metals that are included in the third and fourth conductive patterns 270 and 350, respectively. The third conductive pattern 270 may at least partially cover a lower surface and an outer sidewall of the ninth conductive pattern 800, and the ninth conductive pattern 800 may at least partially cover the lower surface and the lower sidewall of the fourth conductive pattern 350.

The ninth conductive pattern 800 may be formed by an additional thermal treatment process, after the thermal pressing process for bonding the second and third semiconductor chips 200 and 300 with each other, so that the metals included in the third and fourth conductive patterns 270 and 350, respectively, contacting each other may be coupled with each other.

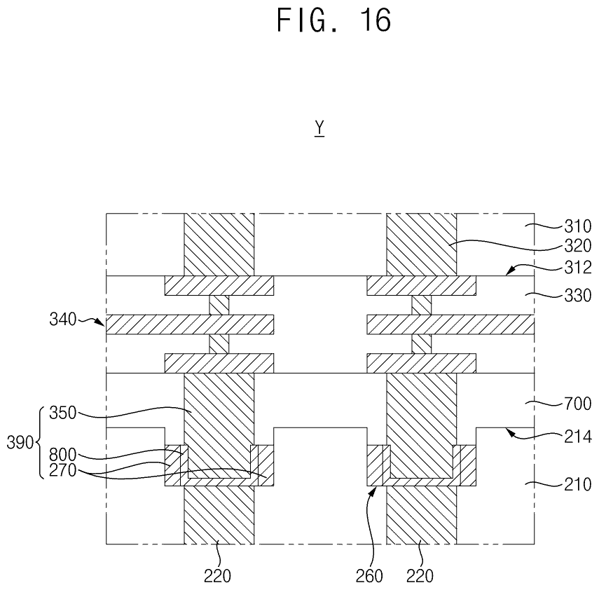

Referring to FIG. 16, the second conductive connector 390 may further include the ninth conductive pattern 800 at the interface between the third and fourth conductive patterns 270 and 350.

The ninth conductive pattern 800 may contact the upper surface of the second through electrode, and the third conductive pattern 270 may at least partially cover the outer sidewall of the ninth conductive pattern 800.

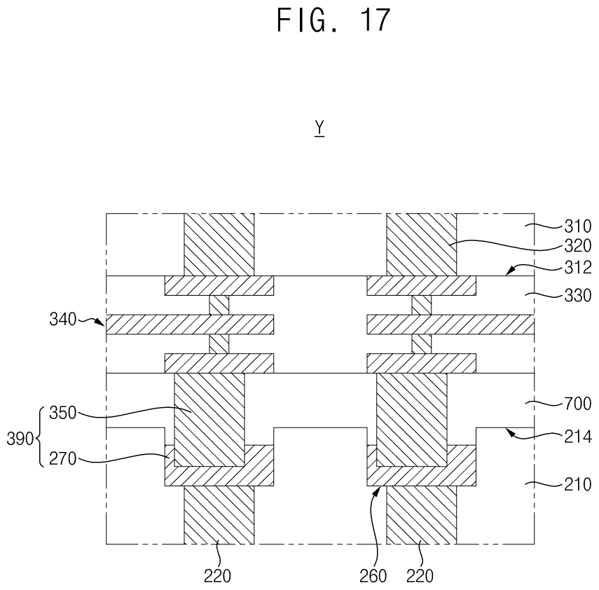

Referring to FIG. 17, the fourth conductive pattern 350 included in the second conductive connector 390 might not be aligned. For example, the fourth conductive pattern 350 may be misaligned with the second through electrode 220 in the second trench 260.

In a plan view, the fourth conductive pattern 350 may at least partially overlap the second through electrode 220, however, a center of the fourth conductive pattern 350 might not be aligned with a center of the second through electrode 220.

However, the fourth conductive pattern 350 may be formed in the second trench 260 and may contact the third conductive pattern 270 having an area greater than that of the fourth conductive pattern 350 and at least partially surrounding the lower portion of the fourth conductive pattern 350. Thus, the electrical connection between the second conductive connector 390 including the fourth conductive pattern 350 and the second through electrode 220 may be strengthened. As used herein, the phrase, “at least partially surrounding” may mean that the first element is proximate to the second element on at least one portion thereof so as to be proximate to it on one side, on opposing sides, or to fully surround it on all sides.

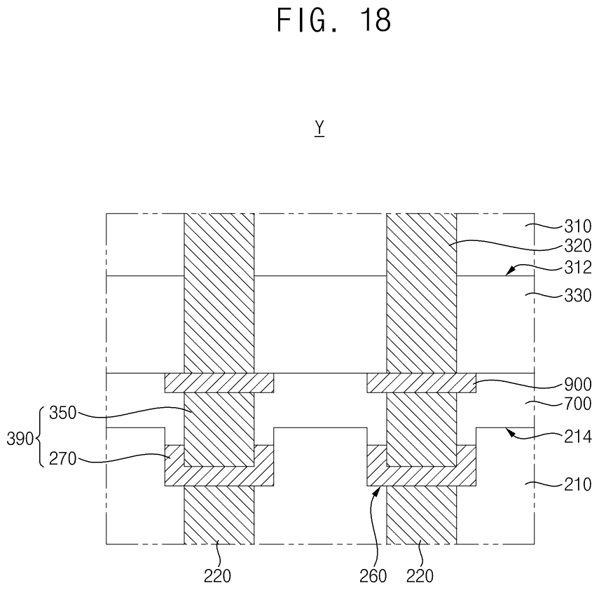

Referring to FIG. 18, the third through electrode 320 may extend through not only the third substrate 310 but also the fifth insulating interlayer and the sixth insulating interlayer 330. A second conductive pad 900 may be additionally formed beneath the sixth insulating interlayer 330 and contact a lower surface of the third through electrode 320.

Thus, an upper surface of the fourth conductive pattern 350 included in the second conductive connector 390 may contact a lower surface of the second conductive pad 900.

In example embodiments of the present invention, an area of the second conductive pad 900 may be greater than that of each of the third through electrode 320 and the fourth conductive pattern 350. The second conductive pad 900 may include a metal such as copper, aluminum, nickel, titanium, etc., or an alloy such as titanium/copper, nickel/gold, titanium/palladium, titanium/nickel, chromium/copper, etc.

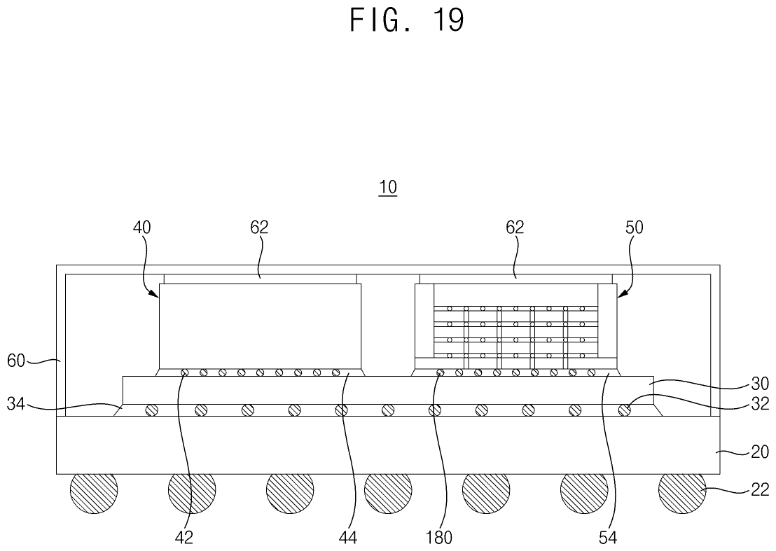

FIG. 19 is a cross-sectional view illustrating an electronic device in accordance with example embodiments of the present invention.

This electronic device may include the semiconductor package shown in FIGS. 1 to 3 as a second semiconductor device 50, however, the inventive concept might not be necessarily limited thereto, and the second semiconductor device 50 may also include the semiconductor packages shown in FIGS. 14 to 18.

Referring to FIG. 19, an electronic device 10 may include a package substrate 20, an interposer 30, a first semiconductor device 40 and the second semiconductor device 50. The electronic device 10 may further include first, second and third underfills 34, 44 and 54, a heat slug 60 and a heat dissipator 62.

In example embodiments of the present invention, the electronic device 10 may be a memory module having a 2.5D package structure, and thus may include the interposer 30 for electrically connecting the first and second semiconductor devices 40 and 50 to each other.

In example embodiments of the present invention, the first semiconductor device 40 may include a logic device, and the second semiconductor device 50 may include a memory device. The logic device may be an application-specific integrated circuit (ASIC) chip including, for example, a central processing unit (CPU), a graphics processing unit (GPU), a micro-processor, a micro-controller, an application processor (AP), a digital signal processing core, etc. The memory device may be the semiconductor package of FIGS. 1 to 3.

In example embodiments of the present invention, the package substrate 20 may have an upper surface and a lower surface opposite to each other in the vertical direction. For example, the package substrate 20 may be a printed circuit board (PCB). The printed circuit board may be a multi-layer circuit board having various circuits therein.

The interposer 30 may be mounted on the package substrate 20 through a seventh conductive connector 32. In example embodiments of the present invention, a planar area of the interposer 30 may be smaller than a planar area of the package substrate 20. The interposer 30 may be disposed within an area of the package substrate 20 in a plan view.

The interposer 30 may be a silicon interposer or a redistribution interposer having a plurality of wirings therein. The first semiconductor device 40 and the second semiconductor device 50 may be connected to each other through the wirings in the interposer 30 or electrically connected to the package substrate 20 through the seventh conductive connector 32. The seventh conductive connector 32 may include, for example, a micro-bump. The silicon interposer may provide a high-density interconnection between the first and second semiconductor devices 40 and 50.

The first semiconductor device 40 may be disposed on the interposer 30. The first semiconductor device 40 may be mounted on and bonded with the interposer 30 by a flip chip bonding process. In this case, the first semiconductor device 40 may be mounted on the interposer 30 such that an active surface on which conductive pads are formed may face downwardly toward the interposer 30. The conductive pads of the first semiconductor device 40 may be electrically connected to conductive pads of the interposer 30 through an eighth conductive connector 42. For example, the eighth conductive connector 42 may include, for example, a micro-bump.

In some embodiments, the first semiconductor device 40 may be mounted on the interposer 30 by a wire bonding process, and in this case, the active surface of the first semiconductor device 40 may face upwardly.

The second semiconductor device 50 may be disposed on the interposer 30, and may be spaced apart from the first semiconductor device 40 in the horizontal direction. The second semiconductor device 50 may be mounted on and bonded with the interposer 30 by, for example, a thermal compression bonding (TCB) process. In this case, conductive pads of the second semiconductor device 50 may be electrically connected to conductive pads of the interposer 30 by the fifth conductive connector 180.

A single first semiconductor device 40 and a single second semiconductor device 50 are disposed on the interposer 30, however, the inventive concept might not be necessarily limited thereto, and a plurality of first semiconductor devices 40 and/or a plurality of second conductive devices 50 may be disposed on the interposer 30.

In example embodiments of the present invention, the first underfill 34 may fill a space between the interposer 30 and the package substrate 20, and the second and third underfills 44 and 54 may fill a space between the first semiconductor device 40 and the interposer 30 and a space between the second semiconductor device 50 and the interposer 30, respectively.

The first to third underfills 34, 44 and 54 may include a material that can flow easily to effectively fill a small space between the first and second semiconductor devices 40 and 50 and the interposer 30 and a small space between the interposer 30 and the package substrate 20. For example, each of the first and second underfills 34, 44 and 54 may include an adhesive containing an epoxy material.

In example embodiments of the present invention, the heat slug 60 may be formed on the package substrate 20 and thermally contact the first and second semiconductor devices 40 and 50. The heat dissipator 62 may be disposed on an upper surface of each of the first and second semiconductor devices 40 and 50, and may include, for example, thermal interface material (TIM). The heat slug 60 may thermally contact the first and second semiconductor devices 40 and 50 via the heat dissipator 62.

A conductive pad may be formed at a lower portion of the package substrate 20, and a sixth conductive connector 22 may be disposed beneath the conductive pad. In example embodiments of the present invention, a plurality of sixth conductive connectors 22 may be spaced apart from each other along the horizontal direction. The sixth conductive connector 22 may be, for example, a solder ball. The electronic device 10 may be mounted on a module board via the sixth conductive connectors 22 and form a memory module.

The foregoing is illustrative of example embodiments and is not necessarily to be construed as limiting thereof. Although a few example embodiments have been described, those skilled in the art will readily appreciate that many modifications are possible in example embodiments without materially departing from the novel teachings and aspects of the present disclosure. Accordingly, all such modifications are intended to be included within the scope of example embodiments.

What is claimed is:

1. A semiconductor package, comprising:
a first semiconductor chip including a substrate;
a second semiconductor chip disposed on the first semiconductor chip;
a conductive connector disposed between the first and second semiconductor chips, wherein the conductive connector electrically connects the first and second semiconductor chips with each other; and
a bonding layer disposed between the first and second semiconductor chips, wherein the bonding layer bonds the first and second semiconductor chips with each other and covers an upper sidewall of the conductive connector,
wherein the first conductive connector includes:
a first conductive pattern disposed at a lower portion of a trench on the substrate and includes a first metal;
a second conductive pattern extending on the first conductive pattern in a vertical direction substantially perpendicular to an upper surface of the substrate and extending through an upper portion of the first conductive pattern and including a second metal; and
a third conductive pattern disposed between the first and second conductive patterns and contacts the first and second conductive patterns and including both the first and second metals.

2. The semiconductor package according to claim 1, wherein a melting point of the first metal is lower than a melting point of the second metal.

3. The semiconductor package according to claim 1, wherein the first metal includes tin, and the second metal includes copper.

4. The semiconductor package according to claim 1, wherein the third conductive pattern at least partially covers a lower surface and a lower sidewall of the second conductive pattern.

5. The semiconductor package according to claim 1, wherein the first conductive pattern at least partially covers a lower surface and a sidewall of the third conductive pattern.

6. The semiconductor package according to claim 1, wherein an upper surface of the first conductive pattern is disposed at lower level than an upper surface of the substrate.

7. The semiconductor package according to claim 1, wherein an area of an upper surface of the first conductive pattern is greater than an area of a lower surface of the second conductive pattern.

8. The semiconductor package according to claim 1, wherein the first semiconductor chip further includes a through electrode penetrating the substrate in a vertical direction substantially perpendicular to an upper surface of the substrate, and
wherein the first conductive pattern contacts an upper surface of the through electrode.

9. The semiconductor package according to claim 8, wherein an area of a lower surface of the first conductive pattern is greater than an area of the upper surface of the through electrode.

10. The semiconductor package according to claim 8, wherein a center of the second conductive pattern is not aligned with a center of the through electrode along the vertical direction.

11. A semiconductor package, comprising:
a buffer die;
memory dies sequentially stacked on the buffer die, wherein each of the memory dies includes a substrate and a through electrode penetrating the substrate;
a conductive connector disposed between the memory dies and electrically connecting the memory dies with each other;
a bonding layer disposed between the memory dies, wherein the bonding layer bonds the memory dies with each other and at least partially surrounds a sidewall of the conductive connector; and
a molding disposed on the buffer die covering sidewalls of the memory dies,
wherein the conductive connector includes:
a first conductive pattern disposed at a lower portion of a trench on the substrate, the trench exposing an upper surface of the through electrode, and the first conductive pattern contacting the upper surface of the through electrode; and
a second conductive pattern extending on the first conductive pattern along a vertical direction substantially perpendicular to an upper surface of the substrate and extending through an upper portion of the first conductive pattern.

12. The semiconductor package according to claim 11, wherein an upper surface of the first conductive pattern is disposed at lower level than an upper surface of the substrate.

13. The semiconductor package according to claim 11, wherein an area of the upper surface of the first conductive pattern is greater than an area of a lower surface of the second conductive pattern.

14. The semiconductor package according to claim 11, wherein a center of the conductive pattern is not aligned with a center of the through electrode along the vertical direction.

15. A semiconductor package, comprising:
a buffer die including a first substrate and a first through electrode penetrating the first substrate in a vertical direction;
memory dies sequentially stacked on the buffer die, wherein each of the memory dies includes a second substrate and a second through electrode penetrating the second substrate in the vertical direction;
a first conductive connector disposed between the buffer die and a lowermost one of the memory dies, wherein the first conductive connector electrically connects the buffer die and the lowermost one of the memory dies with each other;
a first bonding layer between the buffer die and the lowermost one of the memory dies, wherein the first bonding layer bonds the buffer die and the lowermost one of the memory dies with each other and at least partially covers a sidewall of the first conductive connector;
a second conductive connector disposed between the memory dies, wherein the second conductive connector electrically connects the memory dies with each other;
a second bonding layer disposed between the memory dies, wherein the second bonding layer bonds the memory dies with each other and covers a sidewall of the second conductive connector; and
a molding disposed on the buffer die, wherein the molding covers sidewalls of the memory dies,
wherein the second conductive connector includes:
a first conductive pattern extending through an upper portion of the second substrate and contacting an upper surface of the second through electrode; and
a second conductive pattern extending on the first conductive pattern in the vertical direction, the second conductive pattern extending through an upper portion of the first conductive pattern.

16. The semiconductor package according to claim 15, wherein an upper surface of the first conductive pattern is disposed at lower level than an uppermost surface of the second substrate.

17. The semiconductor package according to claim 15, wherein an area of an upper surface of the first conductive pattern is greater than an area of a lower surface of the second conductive pattern.

18. The semiconductor package according to claim 15, wherein a center of the second conductive pattern is aligned with a center of the second through electrode along the vertical direction.

19. The semiconductor package according to claim 15, wherein a center of the second conductive pattern is not aligned with a center of the second through electrode along the vertical direction.

20. The semiconductor package according to claim 15, wherein the first conductive connector includes:
a third conductive pattern extending through an upper portion of the first substrate and contacting an upper surface of the first through electrode; and
a fourth conductive pattern extending on the third conductive pattern in the vertical direction, the fourth conductive pattern extending through an upper portion of the third conductive pattern.
